(19) United States
(12) Patent Application Publication
(10) Pub. No.: US 2009/0322366 A1
(43) Pub. Date: Dec. 31, 2009

(54) Integrated Tester Chip Using Die Packaging Technologies

(75) Inventors: Kenneth Kaskoun, San Diego, CA (US); Sanjay K. Jha, San Diego, CA (US)

Correspondence Address: QUALCOMM INCORPORATED, 5775 MOREHOUSE DR., SAN DIEGO, CA, 92121, US

(73) Assignee: QUALCOMM INCORPORATED, San Diego, CA (US)

(21) Appl. No.: 12/147,918

(22) Filed: Jun. 27, 2008

(51) Int. Cl. G01R 31/26

(52) U.S. Cl. 324/763

(57) ABSTRACT

By constructing a universal test circuit on a tester chip, and stacking the tester chip in an IC package together with operational circuit chips to be tested, the problems inherent with external IC testing are reduced. The tester chip can be standardizes across a number of different chip combinations and, if desired, pre-programmed during manufacturing for a particular package. The tester chip interfaces to other chips in the stack advantageously are standardized.

### TECHNICAL FIELD

This disclosure relates to integrated circuit (IC) testing and more particularly to systems and methods for testing multi-tiered IC devices.

### BACKGROUND

Typically, during the manufacturing process of an IC, testing (probing) is performed on the IC prior to the time the IC is mounted into a package. In some instances the probing is performed after the IC is mounted. However, in situations where multiple ICs are stacked into tiers, it is difficult to probe the ICs due to inaccessibility of test terminals on the outside of the stacked device.

The problem is compounded when a tier does not include a complete circuit. Thus, in situations where portions of a testable circuit are constructed on different tiers, it is not feasible to test the complete circuit until the dies are stacked into the final multi-tiered IC device (also referred to as a stacked IC device). Moreover, once stacked accessibility for test purposes may be limited.

One solution to this problem is to bring test leads to accessible locations on the periphery of the stacked device. This, however, in many situations is either not possible due to space constraints, signal propagation times, or simply because it is too expensive. Another problem is that the small size of stacked devices may require small electrical pads and through silicon vias (TSV), which may range in size to less than 10 microns, which in turn do not easily lend to testing with conventional probe tips (typically 25-50 microns). For testing, multiple probe tips usually must make contact at the same time, so even when each individual probe tip is small enough, a large number of probe tips becomes difficult to manage.

### BRIEF SUMMARY

By constructing a universal test circuit on a die (or chip), and stacking the test die in the IC package together with other dies to be tested, the problems inherent with external IC testing are reduced. In effect, an on-die tester would be created. The tester chip would be standardized across a number of different chip combinations, and if desired, pre-programmed during manufacturing for a particular package. This then would allow tester chips to test a wide variety of different products (chip combinations).

One advantage of such an arrangement is that it decouples tester chip development from the design or fabrication of the operational chip itself. Thus, a company could dedicate resources to working on the tester chip in a continuous mode, independent from a particular product. Consequently, the design of a tester chip would not necessarily need to keep pace with the design schedules for any particular product.

The foregoing has outlined, rather broadly, the features and technical advantages of the present invention in order that the detailed description of the invention that follows may be better understood. Additional features and advantages of the invention will be described hereinafter which form the subject of the claims of the invention. It should be appreciated by those skilled in the art that the conception and specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims. The novel features, which are believed to be characteristic of the invention, both as to its organization and method of operation, together with further objects and advantages, will be better understood from the following description when considered in connection with the accompanying figures. It is to be expressly understood, however, that each of the figures is provided for the purpose of illustration and description only, and is not intended as a definition of the limits of the present invention.

### BRIEF DESCRIPTION OF THE DRAWINGS

For a more complete understanding of the present invention, reference is now made to the following descriptions taken in conjunction with the accompanying drawings, in which:

FIG. 1 shows one configuration of an embodiment of the inventive concept in which a tester chip is contained within an IC package;

FIGS. 2 and 3 show other configurations of different embodiments of the inventive concept in which a tester chip is contained within an IC package;

FIGS. 4 and 5 show examples of chips manufactured as part of wafers according to embodiments of the invention; and

FIG. 6 shows one embodiment of a method of constructing an IC package using the inventive concepts discussed herein.

### DETAILED DESCRIPTION

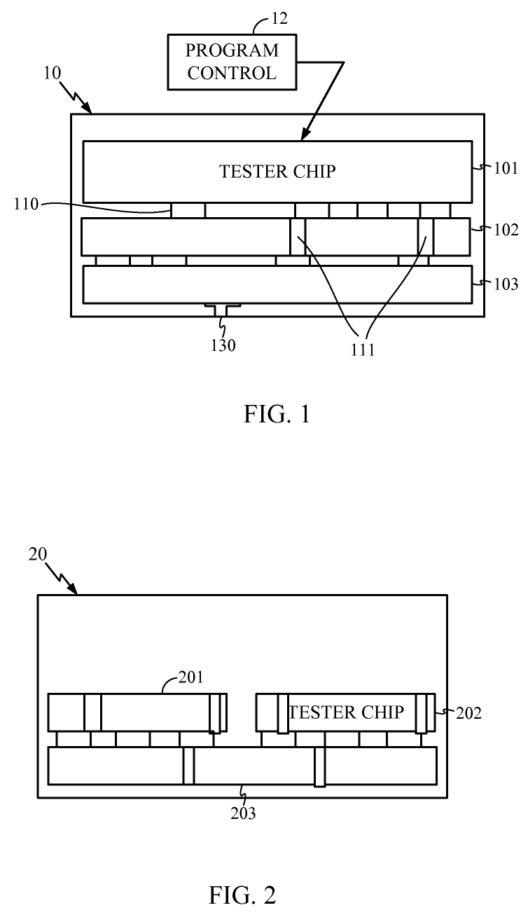

FIG. 1 shows one configuration of an embodiment of the inventive concept in which a tester chip is contained within IC package 10. In the embodiment shown, IC tiers 101, 102, 103 are stacked to create a stacked IC device. This is only one example of how the tiers 101, 102, 103 can be assembled. Note that while three tiers are shown, the concepts discussed herein can be used with any number of tiers, including a single tier.

IC package 10 contains a tester chip in tier 101 electrically connected to one or more chips in tier 102 by contacts 110. The tester chip is the only occupant of the tier (i.e., 101) in the embodiment of FIG. 1. Vias 111 are shown constructed in chips in tier 102 to facilitate heat transfer or electrical connections among the tiers 101, 102, 103. Not shown in tiers 101, 102, 103, are active circuits and other elements formed in chips in the different tiers using standard IC processes all now well-known to those skilled in the art. Contact 130 can be used, for example, to make electrical contact with components outside IC package 10. As will be discussed, a program control 12 optionally can be used to input testing programming control data to IC package 10 to control the tester chip to test one or more circuits on chips in tier 102 and/or tier 103.

The tester chip in tier 101 may be a universal tester chip, meaning that it can be used to test various different circuits and/or circuit combinations. If desired, programming for testing a specific circuit can be built into the tester chip in tier 101 during manufacture, or the tester chip in tier 101 can be built with an ability to receive instructions (programming) at a later time. These instructions can be added to the tester chip in tier 101 before the tester chip is added to an IC package 10 in tier 101 or after. The instructions can be made permanent or temporary, and can be contained in a memory which is also placed into the IC package 10. The memory containing the instructions could be part of the tester chip in tier 101 or added to the tester chip in tier 101 just prior to introducing the tester chip into tier 101 of a specific IC package 10.

Operation of IC package 10 is such that at some point in time, as will be discussed hereinafter, the tester chip in tier 101 is activated, either from an external stimulus, for example via contact 130 or program control 12, to perform testing

As discussed above, in some cases the operational circuitry that is being tested may be circuitry that partially resides on one tier and partially resides on one or more other tiers, all interconnected by contacts 110 and/or vias 111.

FIG. 2 shows another configuration of an embodiment of the inventive concept in which a tester chip 202 is contained within an IC package 20. In this embodiment, tester chip 202 shares the same tier with chip 201 containing one or more operational circuits (not shown). A second tier contains operational chip 203.

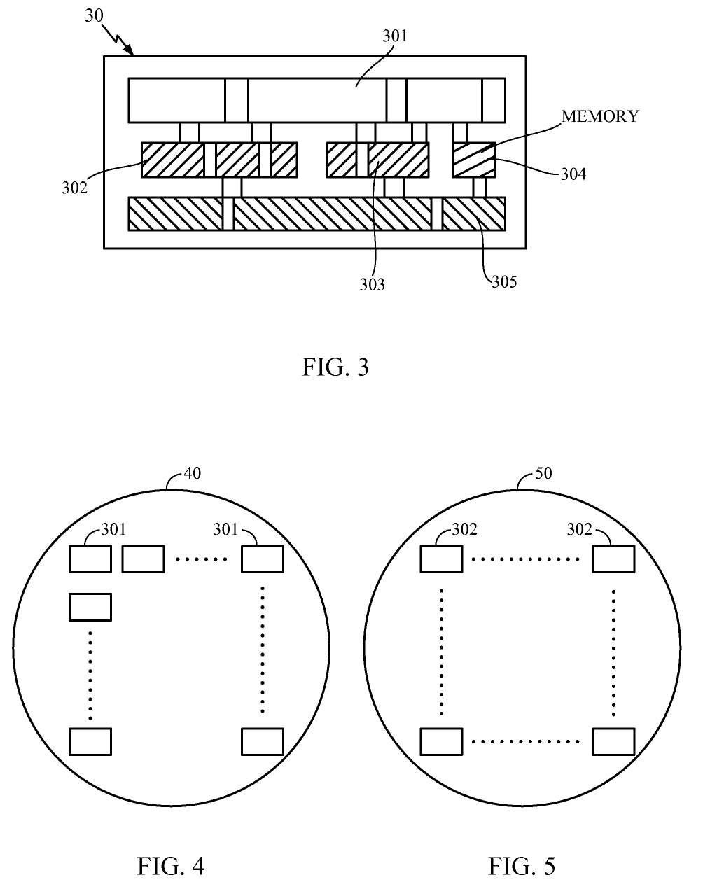

FIG. 3 shows another configuration of an embodiment of the inventive concept in which tester chip 302 is contained within an IC package 30. Memory chip 304 along with operational chip 303 share a tier with the tester chip 302. Programming instructions could be contained within memory 304. These instructions could be programmed into the memory either before the memory is positioned within the IC package 30 or thereafter. If the programming of the memory 304 occurs after the tester chip 302 is sealed within the IC package 30 then the test data can be supplied via contacts on the IC package 30 or via a wireless connection. This wireless connection can be, for example, RF, infrared, or any wireless protocol. The receiver for such wireless transmission can be built into one or more of the chips contained within the IC package 30. Also contained in IC package 30 are operational chips 301 and 305.

FIG. 4 shows an example of chips, such as operational chips 301 being manufactured as part of a wafer, such as wafer 40. In some cases, a portion of each chip 301 can be tested while still part of the wafer. In other situations, such testing may not be feasible.

FIG. 5 shows wafer 50 on which are constructed dies of tester chip 302 which may be universal tester chips as discussed above. Each of these tester chips 302 is constructed the same regardless of which IC package the chip will actually become a part of. In one embodiment, each tester chip 302 can be identified as “belonging” to a particular IC package. In such a situation, if desired, the tester chip 302 can have loaded therein a test program unique to the identified IC package. In other situations, the tester chip 302 will be separated from the wafer 50 prior to any specific programming. In such a situation, as will be discussed, any desired unique programming will be added to the tester chip 302 at a later time.

It should be noted that while the tester chip 302 is shown as being constructed in conjunction with a wafer 50 of similar chips, the tester chip (or chips) 302 can be constructed on the same wafer 50 as the operational circuit chips 301.

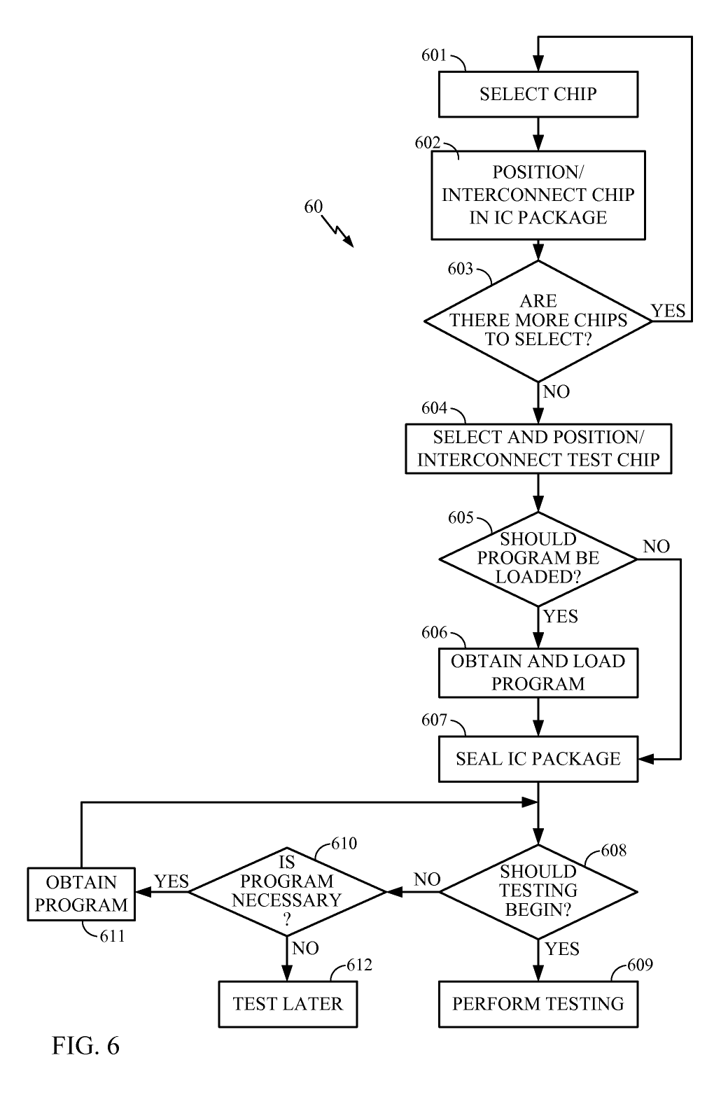

FIG. 6 shows one embodiment 60 of a method of constructing an IC package using the inventive concepts discussed herein. Block 601 controls the selection of a die (or chip) that is to be incorporated into an IC package. The selected die can be pre-tested to the extent possible, but in many situations such pre-testing may not completely test the die for a variety of reasons. One of these reasons may be, as discussed, the fact that a complete operational circuit does not exist until two or more dies are stacked together in a stacked IC device and cooperatively interconnected.

Block 602 positions and interconnects the selected die into the IC package. Block 603 then determines if there are other dies to be added to the package. If so, the other dies are selected and positioned. When all the dies have been properly positioned, interconnected and/or stacked into the package, block 604 selects, positions, and interconnects a universal tester chip. Typically, the stacked IC device would be stacked tier by tier with operational and/or tester chips positioned on a tier and then another tier added. Thus, embodiment 60, or a portion thereof, can be repeated on a tier by tier basis if desired.

Block 605 determines if a test routine program should be loaded into the selected tester chip or into another memory that has been selected to be in the IC package. Such programming would convert the universal tester chip into a more specific tester chip arranged specifically to test the operational circuit chips in the IC package into which the tester chip is to be inserted. If so, then block 606 obtains and loads the proper test program.

Block 607 seals the stacked IC device within a self-contained package. Note that the tester chip, in one embodiment, may be sealed within the package and will remain within the package through the life of the package. In other embodiments, the tester chip is positioned in such a manner that it, or part of it, may be removed after testing. For example, if the tester chip were to be positioned on a top or bottom tier, then after testing the tier containing the tester chip could be removed if the test chip is the only chip on the tier, or only the test chip could be removed, if other chips exist on the tier. Removal would also be possible if the tester chip(s) were mounted at one end of the IC package.

Blocks 608 and 609 control the timing of the testing of the circuits under control of the associated tester chip in conjunction with any added programming. In some situations, external stimuli can be provided, as discussed above, to initiate and/or control the testing of the stacked IC device.

If testing is not to begin, as determined by block 608, then block 610 determines if a test program or other stimulus is required. If not, testing is performed at a later time as controlled by block 612. If block 610 determines that additional programs or stimuli are required then block 611 obtains the necessary programs and/or stimuli. Block 608 then again determines if it is time for testing to begin.

Note that embodiment 60 shows that the tester chip is selected after the other chips are selected and positioned. This is but one embodiment and the tester chip can be selected at any time and positioned at any time in any desired tier of the IC device.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A tester chip containing a test circuit operable for testing any one of a number of different operational circuits, wherein said different operational circuits are mounted in a same IC package with said test circuit.

2. The tester chip of claim 1 wherein said tester chip can be removed from said package without interfering with normal operation of said mounted operational circuits within said package.

3. The tester chip of claim 1 wherein said IC package has a plurality of tiers of IC devices and said tester chip is mounted on one of said tiers.

4. The tester chip of claim 1 further comprising:
a computer readable medium storing a program designed to control said test circuit on said tester chip such that said test circuit performs validation testing on said operational circuits.

5. The tester chip of claim 4 wherein said program is contained in a memory separate from said tester chip.

6. The tester chip of claim 5 wherein said memory is mounted on one of a plurality of tiers of IC devices within the IC package.

7. The tester chip of claim 6 wherein said program is downloaded to said memory after said memory is positioned in said IC package.

8. A method for testing a stacked IC device within an IC package, said method comprising:
positioning a plurality of chips on a plurality of tiers of said stacked IC package, said positioning comprising electrically coupling said plurality of chips such that said coupled chips function as a device; and
testing a function of said device under control of at least one of said interconnected chips.

9. The method of claim 8 further comprising:
providing test instructions to at least one of the chips.

10. The method of claim 9 wherein said test instructions are provided to at least one of said chips prior to said positioning.

11. An IC package comprising:
at least one operational circuit constructed on a first chip; and
a test circuit constructed on a second chip that is coupled to the first chip, said test circuit capable of testing said operational circuit, as well as a plurality of different types of operational circuits.

12. The package of claim 11 wherein said at least one operational circuit is constructed on different chips, said different chips stacked together within said IC package.

13. The package of claim 11 further comprising:
means for receiving operational instructions unique to said at least one operational circuit, said operational instructions being used to configure said test circuit.

14. The package of claim 13 wherein said operational instructions are contained in a memory resident within said IC package.

15. The package of claim 13 wherein said receiving means comprises:
wireless reception.

16. A method for constructing a stacked IC device, said method comprising:
selecting a plurality of different chips;
selecting at least one tester chip capable of testing a plurality of different combinations of coupled chips; and
stacking said chips, including said tester chip, such that portions of said chips become electrically coupled, wherein said stacked chips form said stacked IC device.

17. The method of claim 16 further comprising:
programming said tester chip to perform testing on said stacked chips.

18. The method of claim 17 further comprising:
removing at least a portion of said tester chip after said testing is performed.

19. The method of claim 17 wherein said programming is performed prior to said stacking.

20. The method of claim 17 wherein said programming is performed from time to time.

21. The method of claim 20 wherein said time to time programming is wirelessly communicated to said stacked IC device.
